(19) United States
(12) Patent Application Publication
(10) Pub. No.: US 2026/0255942 A1
(43) Pub. Date: Aug. 27, 2026

(54) SEMICONDUCTOR STRUCTURE AND FABRICATION METHOD THEREOF

(71) Applicant: UNITED MICROELECTRONICS CORP, Hsin-Chu City (TW)

(72) Inventors: Hung-Yi Wu, Keelung City (TW); Yi-Wen Chen, Tainan City (TW)

(73) Assignee: UNITED MICROELECTRONICS CORP., Hsin-Chu City (TW)

(21) Appl. No.: 19/075,800

(22) Filed: Mar. 11, 2025

(30) Foreign Application Priority Data
Feb. 26, 2025 (TW) 114107012

(51) Int. Cl. H10W 20/20; H10W 20/00; H10W 42/00; H10D 1/68

(52) U.S. Cl. CPC H10W 20/20; H10W 20/023; H10W 42/121; H10D 1/714; H10D 1/716; H10W 20/056; H10W 20/076

(57) ABSTRACT

A semiconductor structure includes a substrate having at least one through substrate via (TSV) forming region thereon; a dielectric layer disposed on the substrate; and at least one through substrate via disposed in the TSV forming region and penetrating through the dielectric layer and into the substrate. The at least one through substrate via comprises a plurality of stress-relief slits elongating in a radial direction.

### BACKGROUND OF THE INVENTION

### Field of the Invention

The present invention relates to the field of semiconductor technology, and more particularly to an improved through-silicon via (TSV) structure suitable for application in silicon interposers.

### Description of the Prior Art

The application of TSV interposers is primarily in advanced semiconductor packaging, serving as an interconnection platform to provide high-density interconnects. With the development of 3D packaging, the use of TSV interposers has become increasingly widespread, and their reliability has garnered growing attention.

In the fabrication process of TSV interposers, an annealing treatment is typically performed after copper electroplating. However, it has been observed that after annealing, the liner layer or glue layer in the TSV structure cannot withstand the stress, resulting in cracking. The copper in the TSV structure can then form copper extrusion defects through these cracks, which adversely affects the reliability of the interposer.

### SUMMARY OF THE INVENTION

It is one objective of this invention to provide an improved semiconductor structure in order to address the deficiencies or drawbacks of the prior art.

One aspect of the invention provides a semiconductor structure including a substrate having at least one through substrate via (TSV) forming region thereon; a dielectric layer disposed on the substrate; and at least one through substrate via disposed in the TSV forming region and penetrating through the dielectric layer and into the substrate. The at least one through substrate via comprises a plurality of stress-relief slits elongating in a radial direction.

According to some embodiments, the plurality of stress-relief slits extend in a longitudinal direction through an entire thickness of the at least one through substrate via, and wherein the at least one through substrate via has a circular shape when viewed from above.

According to some embodiments, the plurality of stress-relief slits are symmetrically distributed around a circumference of the at least one through substrate via.

According to some embodiments, the at least one through substrate via has a gearwheel shape when viewed from above, comprising a plurality of cog portions, and wherein the plurality of stress-relief slits are disposed between the plurality of cog portions.

According to some embodiments, each of the plurality of stress-relief slits comprise two longer sides having a length of W/5 and a base having a width of W/10, where W is a width of the at least one through substrate via.

According to some embodiments, an included angle between one of the two longer sides and the bottom side is equal to or greater than 90 degrees.

According to some embodiments, the at least one through substrate via comprises a copper core layer, a glue layer surrounding the copper core layer, and a liner oxide layer surrounding the glue layer.

According to some embodiments, the dielectric layer and the substrate extend into the plurality of stress-relief slits.

According to some embodiments, the substrate comprises a plurality of device regions, and wherein the at least one TSV forming region is disposed between the plurality of device regions.

According to some embodiments, the plurality of device regions are deep trench capacitor regions.

Another aspect of the invention provides a method for forming a semiconductor structure. A substrate having at least one through substrate via (TSV) forming region thereon is provided. A dielectric layer is formed on the substrate. At least one through substrate via is formed in the TSV forming region. The at least one through substrate via penetrates through the dielectric layer and into the substrate. The at least one through substrate via comprises a plurality of stress-relief slits elongating in a radial direction.

According to some embodiments, the plurality of stress-relief slits extend in a longitudinal direction through an entire thickness of the at least one through substrate via, and wherein the at least one through substrate via has a circular shape when viewed from above.

According to some embodiments, the plurality of stress-relief slits are symmetrically distributed around a circumference of the at least one through substrate via.

According to some embodiments, the at least one through substrate via has a gearwheel shape when viewed from above, comprising a plurality of cog portions, and wherein the plurality of stress-relief slits are disposed between the plurality of cog portions.

According to some embodiments, each of the plurality of stress-relief slits comprises two longer sides having a length of W/5 and a base having a width of W/10, where W is a width of the at least one through substrate via.

According to some embodiments, an included angle between one of the two longer sides and the bottom side is equal to or greater than 90 degrees.

According to some embodiments, the at least one through substrate via comprises a copper core layer, a glue layer surrounding the copper core layer, and a liner oxide layer surrounding the glue layer.

According to some embodiments, the dielectric layer and the substrate extend into the plurality of stress-relief slits.

According to some embodiments, the substrate comprises a plurality of device regions, and wherein the at least one TSV forming region is disposed between the plurality of device regions.

According to some embodiments, the plurality of device regions are deep trench capacitor regions.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial top-view schematic diagram of a semiconductor structure according to an embodiment of the present invention.

FIG. 2 is a cross-sectional schematic diagram taken along line I-I’ shown in FIG. 1.

FIGS. 3-5 are schematic diagrams illustrating a method for fabricating a semiconductor structure according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

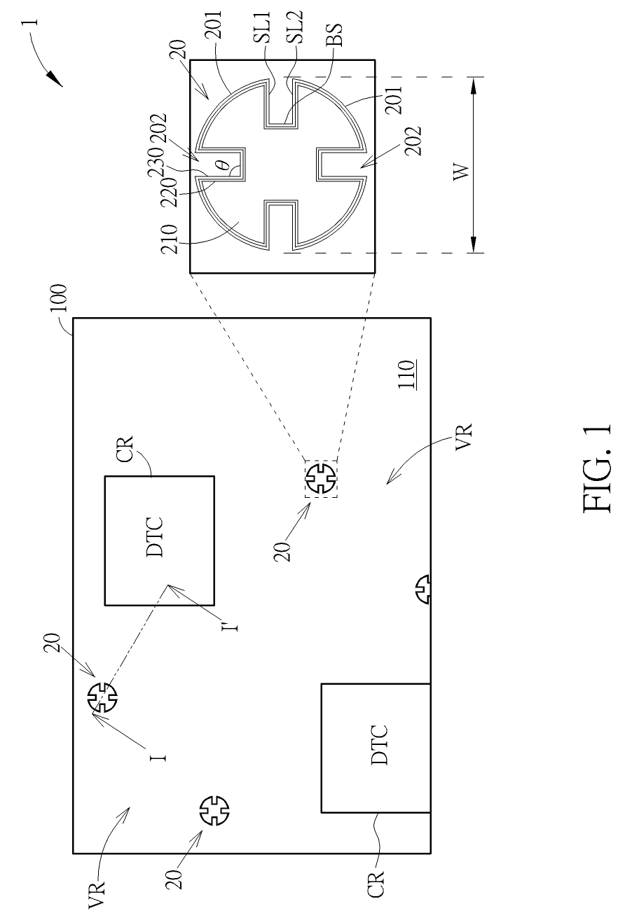

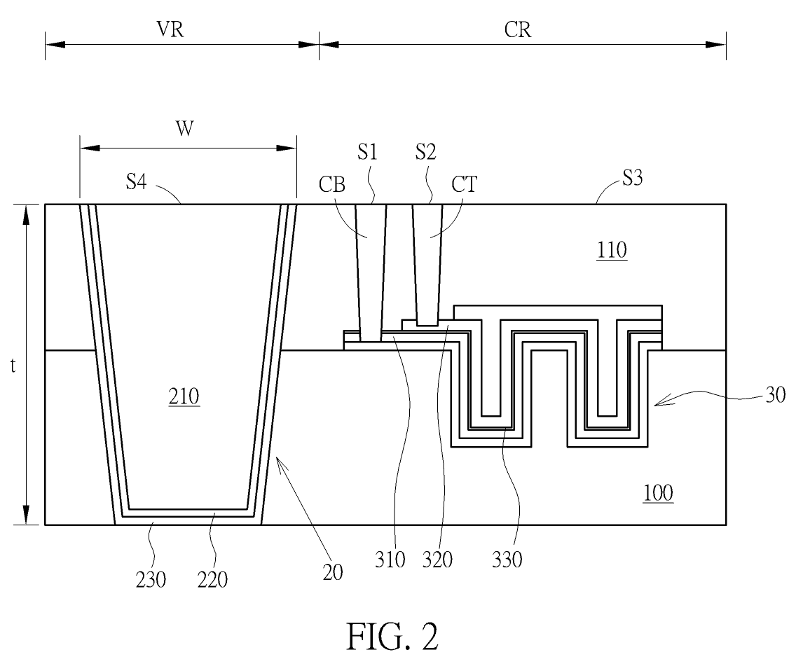

Please refer to FIG. 1 and FIG. 2, where FIG. 1 is a partial top-view schematic diagram of a semiconductor structure according to an embodiment of the present invention, and FIG. 2 is a cross-sectional schematic diagram taken along line I-I’ shown in FIG. 1. As shown in FIG. 1 and FIG. 2, the semiconductor structure 1 includes a substrate 100, such as a silicon substrate, but not limited thereto. According to an embodiment of the present invention, the substrate 100 includes a plurality of device regions CR and at least one through-silicon via (TSV) forming region VR, wherein the at least one TSV forming region VR is disposed between the plurality of device regions CR. According to an embodiment of the present invention, the device regions CR are deep trench capacitor (DTC) regions.

Within the at least one TSV forming region VR, a plurality of through-silicon vias 20 are provided. According to an embodiment of the present invention, each of the through-silicon vias 20, when viewed from above, may have an approximately circular outline, and the width (or diameter) of each of the through-silicon vias 20 is W, for example, W = 11 micrometers, but not limited thereto.

It should be understood that the layout of the device regions CR and the plurality of through-silicon vias 20 in FIG. 1 is for illustration purposes only. For example, in some embodiments, the plurality of device regions CR may be arranged in a checkerboard staggered pattern or may be neatly aligned in multiple rows.

As shown in FIG. 2, the semiconductor structure 1 further includes at least one trench capacitor structure 30 disposed within each device region CR. According to an embodiment of the present invention, the trench capacitor structure 30 includes, for example, a lower electrode 310, an upper electrode 320, and a capacitor dielectric layer 330 positioned between the lower electrode 310 and the upper electrode 320.

As shown in FIG. 1 and FIG. 2, the semiconductor structure 1 further includes a dielectric layer 110 disposed on the substrate 100. According to an embodiment of the present invention, the dielectric layer 110 is, for example, a TEOS-based silicon oxide layer with a thickness of approximately 3000-5000 angstroms, such as 3800 angstroms. According to an embodiment of the present invention, the dielectric layer 110 covers the trench capacitor structure 30. According to an embodiment of the present invention, the through-silicon via 20 penetrates the dielectric layer 110 and extends into the substrate 100. According to an embodiment of the present invention, the thickness t of the through-silicon via 20 is, for example, approximately 106 micrometers, though it is not limited to this value.

As shown in FIG. 2, the dielectric layer 110 further includes a contact plug CB and a contact plug CT, which are electrically connected to the lower electrode 310 and the upper electrode 320 of the trench capacitor structure 30, respectively. According to an embodiment of the present invention, the upper surface S1 of the contact plug CB, the upper surface S2 of the contact plug CT, the upper surface S3 of the dielectric layer 110, and the upper surface S4 of the through-silicon via 20 are coplanar.

According to an embodiment of the present invention, the through-silicon via 20 includes a copper core layer 210, a glue layer 220 surrounding the copper core layer 210, and a liner oxide layer 230 surrounding the adhesion layer 220, wherein the liner oxide layer 230 directly contacts the dielectric layer 110 and the substrate 100. According to an embodiment of the present invention, the glue layer 220 is, for example, TiN or TaN, but is not limited thereto. According to an embodiment of the present invention, the liner oxide layer 230 is, for example, a silicon oxide layer, but is not limited thereto.

As shown in the partial enlarged view of FIG. 1, according to an embodiment of the present invention, the through-silicon via 20, when viewed from above, has a gearwheel shape, including a plurality of cog portions 201 and a plurality of radially extending stress-relief slits 202, wherein the stress-relief slits 202 are disposed between the cog portions 201 and are symmetrically distributed around the circumference of the through-silicon via 20. Although only four stress-relief slits 202 are shown in the figure, it should be understood that in some embodiments, the number of stress-relief slits 202 may exceed four.

According to an embodiment of the present invention, each stress-relief slit 202 includes two long sides SL1 and SL2, with lengths, for example, less than or equal to W/5, and a base side BS, with a width, for example, less than or equal to W/10, where W is the width of the through-silicon via. According to an embodiment of the present invention, the angle θ between one of the two long sides SL1 and SL2 and the base side BS is equal to or greater than 90 degrees.

According to an embodiment of the present invention, the dielectric layer 110 and the substrate 100 extend into the plurality of stress relief slits 202 and closely interlock with the plurality of cog portions 201 of the through-silicon via 20. According to an embodiment of the present invention, the plurality of stress relief slits 202 extend longitudinally through the entire thickness t of the through-silicon via 20.

Through an innovative structural layout design of the through-silicon via, the present invention optimizes stress distribution, effectively preventing cracks in the liner layer or glue layer within the TSV structure caused by annealing after copper plating, thereby improving product reliability and yield.

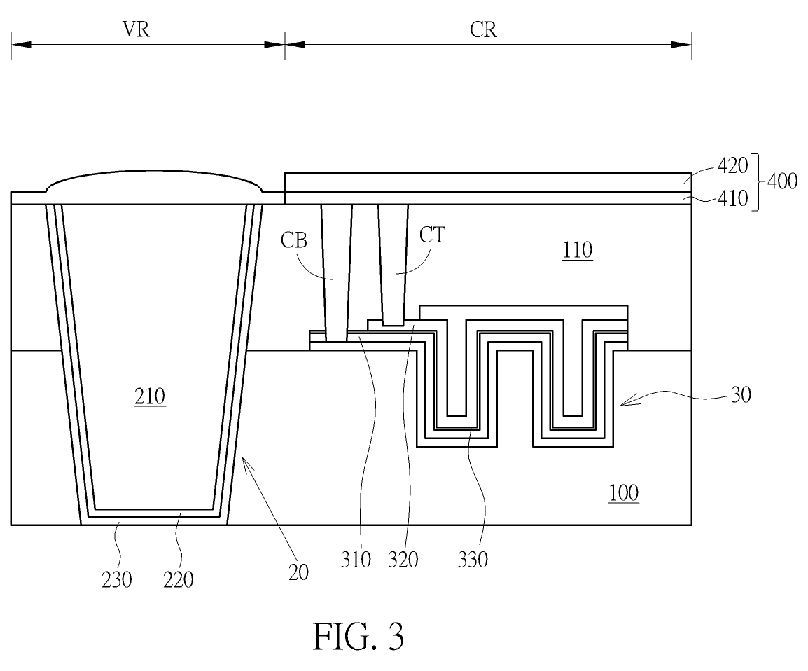

Please refer to FIGS. 3-5, which are schematic diagrams illustrating a method for fabricating a semiconductor structure according to an embodiment of the present invention. As shown in FIG. 3, first, a substrate 100 is provided, having at least one device region CR and at least one through-silicon via (TSV) forming region VR thereon. A trench capacitor structure 30 is formed within the device region CR. According to an embodiment of the present invention, the trench capacitor structure 30 may include, for example, a lower electrode 310, an upper electrode 320, and a capacitor dielectric layer 330.

Next, a chemical vapor deposition (CVD) process is performed to deposit a dielectric layer 110 over the substrate 100 in a blanket manner. According to an embodiment of the present invention, the dielectric layer 110 is, for example, a TEOS-based silicon oxide layer with a thickness of approximately 3000-5000 Å, such as 3800 Å. According to an embodiment of the present invention, the dielectric layer 110 covers the trench capacitor structure 30. Subsequently, contact plugs CB and CT are formed in the dielectric layer 110, electrically connecting to the lower electrode 310 and the upper electrode 320 of the trench capacitor structure 30, respectively.

Subsequently, a hard mask layer 400 is deposited over the entire surface of the dielectric layer 110. For example, the hard mask layer 400 may include a silicon nitride layer 410 and a silicon oxide capping layer 420.

Next, a through-silicon via (TSV) process is performed, including steps such as lithography, etching, copper plating, and chemical mechanical polishing, to form a through-silicon via 20 within the TSV forming region VR. According to an embodiment of the present invention, the through-silicon via 20 penetrates the hard mask layer 400, the dielectric layer 110, and extends into the substrate 100.

According to an embodiment of the present invention, the through-silicon via 20 includes a copper core layer 210, a glue layer 220 surrounding the copper core layer 210, and a liner oxide layer 230 surrounding the glue layer 220, wherein the liner oxide layer 230 directly contacts the dielectric layer 110 and the substrate 100. According to an embodiment of the present invention, the glue layer 220 is, for example, TiN or TaN, but not limited thereto. According to an embodiment of the present invention, the liner oxide layer 230 is, for example, a silicon oxide layer, but not limited thereto.

Similarly, as shown in FIG. 1, when viewed from above, the through-silicon via 20 has an approximately circular outline, and the width (or diameter) of the through-silicon via 20 is W, for example, W = 11 micrometers, but not limited thereto. As shown in the partial enlarged view of FIG. 1, the through-silicon via 20, when viewed from above, has a gearwheel shape, including a plurality of cog portions 201 and a plurality of radially extending stress-relief slits 202, wherein the stress-relief slits 202 are disposed between the cog portions 201 and are symmetrically distributed around the circumference of the through-silicon via 20.

Likewise, as shown in FIG. 1, each stress-relief slit 202 includes two long sides SL1 and SL2, with lengths, for example, less than or equal to W/5, and a bottom side BS, with a width, for example, less than or equal to W/10, where W is the width of the through-silicon via. According to an embodiment of the present invention, the angle θ between one of the two long sides SL1 and SL2 and the bottom side BS is equal to or greater than 90 degrees.

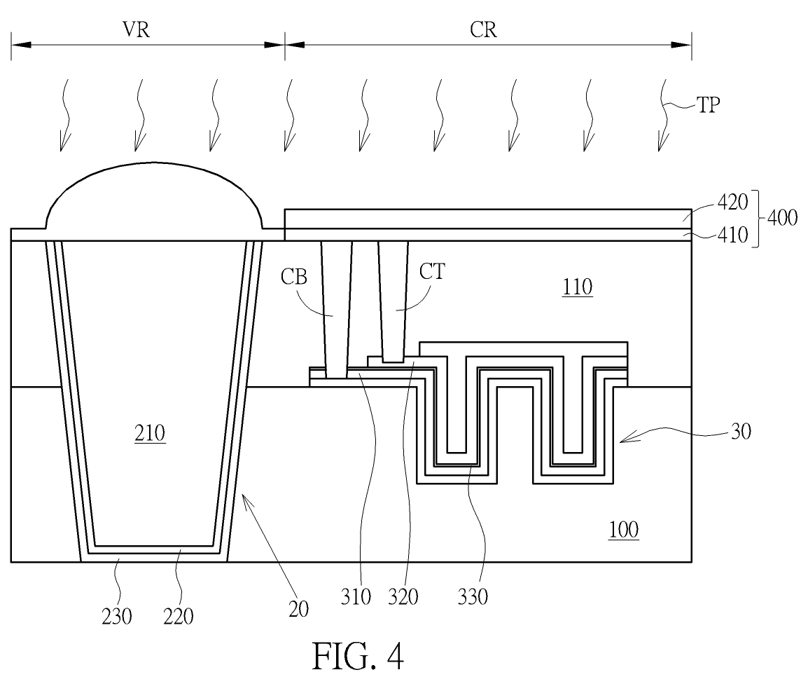

As shown in FIG. 4, after completing the electroplating and mechanical polishing of the copper core layer 210 of the through-silicon via 20, an annealing process TP is performed.

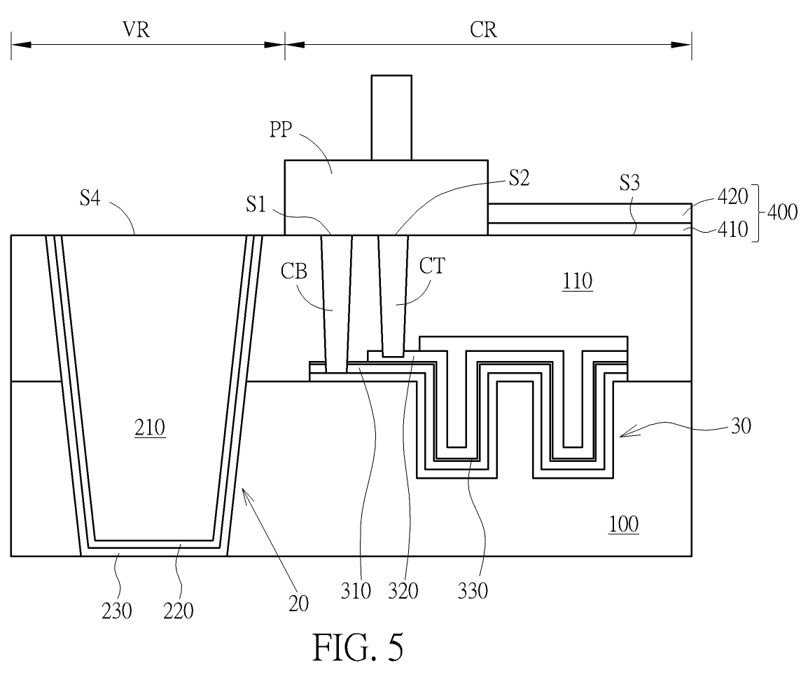

As shown in FIG. 5, subsequently, a chemical mechanical polishing process PP is carried out to remove the copper core layer 210 and the hard mask layer 400 above the dielectric layer 110. At this point, the upper surface S1 of the contact plug CB, the upper surface S2 of the contact plug CT, the upper surface S3 of the dielectric layer 110, and the upper surface S4 of the through-silicon via 20 are coplanar.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate having at least one through substrate via (TSV) forming region thereon;
a dielectric layer disposed on the substrate; and
at least one through substrate via disposed in the TSV forming region and penetrating through the dielectric layer and into the substrate, wherein the at least one through substrate via comprises a plurality of stress-relief slits elongating in a radial direction.

2. The semiconductor structure according to claim 1, wherein the plurality of stress-relief slits extends in a longitudinal direction through an entire thickness of the at least one through substrate via, and wherein the at least one through substrate via has a circular shape when viewed from above.

3. The semiconductor structure according to claim 1, wherein the plurality of stress-relief slits are symmetrically distributed around a circumference of the at least one through substrate via.

4. The semiconductor structure according to claim 1, wherein the at least one through substrate via has a gearwheel shape when viewed from above, comprising a plurality of cog portions, and wherein the plurality of stress-relief slits are disposed between the plurality of cog portions.

5. The semiconductor structure according to claim 1, wherein each of the plurality of stress-relief slits comprise two longer sides having a length of W/5 and a base having a width of W/10, where W is a width of the at least one through substrate via.

6. The semiconductor structure according to claim 5, wherein an included angle between one of the two longer sides and the bottom side is equal to or greater than 90 degrees.

7. The semiconductor structure according to claim 1, wherein the at least one through substrate via comprises a copper core layer, a glue layer surrounding the copper core layer, and a liner oxide layer surrounding the glue layer.

8. The semiconductor structure according to claim 1, wherein the dielectric layer and the substrate extend into the plurality of stress-relief slits.

9. The semiconductor structure according to claim 1, wherein the substrate comprises a plurality of device regions, and wherein the at least one TSV forming region is disposed between the plurality of device regions.

10. The semiconductor structure according to claim 9, wherein the plurality of device regions are deep trench capacitor regions.

11. A method for forming a semiconductor structure, comprising:
providing a substrate having at least one through substrate via (TSV) forming region thereon;
forming a dielectric layer on the substrate; and
forming at least one through substrate via in the TSV forming region, wherein the at least one through substrate via penetrates through the dielectric layer and into the substrate, wherein the at least one through substrate via comprises a plurality of stress-relief slits elongating in a radial direction.

12. The method according to claim 11, wherein the plurality of stress-relief slits extend in a longitudinal direction through an entire thickness of the at least one through substrate via, and wherein the at least one through substrate via has a circular shape when viewed from above.

13. The method according to claim 11, wherein the plurality of stress-relief slits are symmetrically distributed around a circumference of the at least one through substrate via.

14. The method according to claim 11, wherein the at least one through substrate via has a gearwheel shape when viewed from above, comprising a plurality of cog portions, and wherein the plurality of stress-relief slits are disposed between the plurality of cog portions.

15. The method according to claim 11, wherein each of the plurality of stress-relief slits comprise two longer sides having a length of W/5 and a base having a width of W/10, where W is a width of the at least one through substrate via.

16. The method according to claim 15, wherein an included angle between one of the two longer sides and the bottom side is equal to or greater than 90 degrees.

17. The method according to claim 11, wherein the at least one through substrate via comprises a copper core layer, a glue layer surrounding the copper core layer, and a liner oxide layer surrounding the glue layer.

18. The method according to claim 11, wherein the dielectric layer and the substrate extend into the plurality of stress-relief slits.

19. The method according to claim 11, wherein the substrate comprises a plurality of device regions, and wherein the at least one TSV forming region is disposed between the plurality of device regions.

20. The method according to claim 19, wherein the plurality of device regions are deep trench capacitor regions.
